(19) United States
(12) Patent Application Publication
(10) Pub. No.: US 2025/0157860 A1
(43) Pub. Date: May 15, 2025

(54) INTEGRATED CIRCUIT PAD WITH MULTIPLE PROBING AREAS AND METHOD OF PROBING AN INTEGRATED CIRCUIT

(71) Applicant: STMicroelectronics International N.V., Geneva (CH)

(72) Inventors: Alberto PAGANI, Nova Milanese (IT); Mattia DE NICOLA, Burago Di Molgora (IT)

(73) Assignee: STMicroelectronics International N.V., Geneva (CH)

(21) Appl. No.: 18/388,571

(22) Filed: Nov. 10, 2023

(51) Int. Cl. H01L 21/66

(52) U.S. Cl. CPC H01L 22/14; H01L 22/34

(57) ABSTRACT

Wafer level testing is performed on a wafer including integrated circuit dies, each integrated circuit die including a die pads, with each die pad covered by a protection layer. The wafer level testing includes, at a given die pad: puncturing through the protection layer with a distal end of a probe to make physical and electrical contact with the given die pad at a first location at the given die pad; performing a first electrical test of the integrated circuit die through the probe; horizontally translating after completion of the first electrical test; puncturing through the protection layer with the distal end of the probe to make physical and electrical contact with the given die pad at a second location, different from the first location, at the given die pad; and performing a second first electrical test of the integrated circuit die through the probe.

### TECHNICAL FIELD

The present disclosure generally concerns wafer probing and the configuration of integrated circuit pads for wafer probing.

### BACKGROUND

Integrated circuits are typically tested at wafer level subsequent to manufacture. For example, the testing can occur after a full or partial completion of wafer fabrication, and for example after the back end of line (BEOL) fabrication in wafer fab and before die preparation (such as singulation). Wafer level testing is performed using an automatic test equipment while the wafer is inside a wafer prober as referred in the art. This test equipment mechanically and electrically interacts with dies on the wafer using probes which make physical and electrical contact with corresponding integrated circuit pads to apply power and signals into the die and read signals output from the die. The probes may be configured as needles (for example, cantilever needles, or vertical needles or MEMS structures) that are coupled to a probe card, and the wafer is robotically manipulated for horizontal (x-y plane) translation to align the needles to locations of the integrated circuit pads and vertical translation (z-axis) to move the ends (also referred to as tips or probe tips) of the needles into and out of contact with the pads.

### SUMMARY

In an embodiment, wafer level testing is performed on a wafer including integrated circuit dies, each integrated circuit die including a plurality of die pads, each die pad covered by a protection layer. Performing the wafer level testing comprises, at a given die pad of said plurality of die pads: puncturing through the protection layer with a distal end of a probe to make physical and electrical contact with the given die pad at a first location at the given die pad; performing a first electrical test of the integrated circuit die through the probe; horizontally translating (the probe, the wafer, or both) after completion of the first electrical test; puncturing through the protection layer with the distal end of the probe to make physical and electrical contact with the given die pad at a second location, different from the first location, at the given die pad; and performing a second first electrical test of the integrated circuit die through the probe.

In an embodiment, an integrated circuit die comprises: a plurality of wafer test die pads; wherein each wafer test die pad is covered by a protection layer; wherein each wafer test die pad has a geometric shape characterized by a major axis of reflectional symmetry; wherein the major axes of reflectional symmetry for all of the plurality of wafer test die pads extend substantially parallel to each other; and wherein a physical pad of each wafer test die pad in said plurality of wafer test die pads includes a first logical pad within the physical pad with a first test probe mark through the protection layer located within an area of the first logical pad, and a second logical pad within the physical pad with a second test probe mark through the protection layer located within an area of the second logical pad.

### BRIEF DESCRIPTION OF THE DRAWINGS

The foregoing and other features and advantages will be discussed in detail in the following non-limiting description of specific embodiments in connection with the accompanying drawings, in which:

FIGS. 1A-1C illustrate a sequence of operations for wafer level testing;

FIGS. 2A and 2B show a vertical cross-section view and a horizontal cross-section view, respectively, of a die pad configured to be probed;

FIGS. 3A and 3B show a vertical cross-section view and a horizontal cross-section view, respectively, of the die pad in connection with probing action;

FIGS. 4A and 4B show a vertical cross-section view and a horizontal cross-section view, respectively, of the die pad in connection with two probing actions taken at one die pad;

FIGS. 5 and 6 show top plan views of an area where an integrated circuit is located on a wafer illustrating different arrangements of die pads supporting two probing actions;

FIGS. 7A-7C show different geometric shapes supporting multiple horizontally offset probe contact locations;

FIGS. 8A and 8B show a vertical cross-section view and a horizontal cross-section view, respectively, of the die pad in connection with completed probing actions followed by creation of an electrical connection;

FIGS. 9A-9D show different geometric shapes supporting multiple horizontally offset probe contact locations with fiducial marks;

FIG. 10 illustrates process actions for making multiple probing actions;

FIGS. 11A-11K illustrate a sequence of operations for making multiple probing actions;

FIGS. 12A-12B show geometric shapes supporting multiple horizontally offset probe contact locations with fiducial marks; and

FIGS. 13A-13I illustrate a sequence of operations for making multiple probing actions.

### DETAILED DESCRIPTION

The same elements have been designated with the same reference numerals in the different drawings. In particular, the structural and/or functional elements common to the different embodiments may be designated with the same reference numerals and may have identical structural, dimensional, and material properties.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more intermediate elements.

The terms “about”, “substantially”, and “approximately” are used herein to designate a tolerance of plus or minus 10%, preferably of plus or minus 5%, of the value in question.

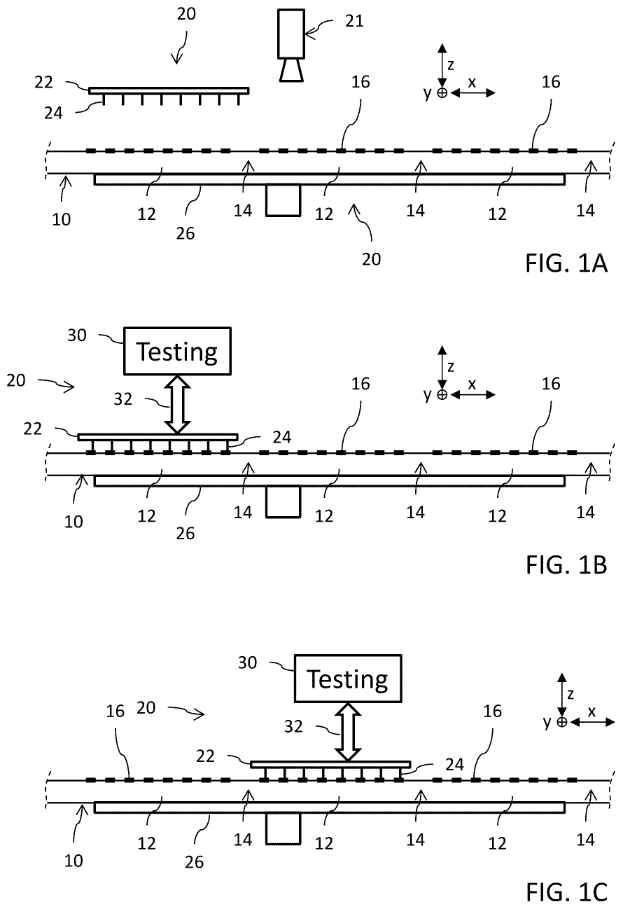

Reference is now made to FIGS. 1A-1C which illustrate a sequence of operations for wafer level testing. A wafer 10 includes a plurality of integrated circuits 12 separated from each other by scribe areas 14 of the wafer. Each integrated circuit 12 includes a plurality of die pads 16 at the upper surface of the wafer. Wafer level test equipment 20 includes a probe card 22 with a plurality of probe needles 24 and a robotic actuation system 26 that is configured to horizontally translate the wafer 10 relative to the probe card 22 in the x-y plane and vertically translate the wafer 10 relative to the probe card 22 in the z direction.

As shown in FIG. 1B, the wafer 10 has been horizontally translated in the x-y plane to a position where the probe card 22 is aligned with the die pads 16 of one or more integrated circuits 12 and the wafer 10 has been vertically translated in the z direction down so that the probe needles 24 make physical and electrical contact with the die pads 16. A testing equipment 30 applies power and signals to the die through the needles 24 of the probe card 22 and reads signals output from the die (the power/signals generally indicated by double headed arrow 32). From the read signals output from the die, the testing equipment 30 may determine whether the die is defective.

FIG. 1C shows the horizontal and vertical translation of the wafer 10 to another position with the needles 24 of the probe card 22 in alignment with the die pads 16 of one or more other integrated circuits 12 for testing. The process is repeated until testing of the integrated circuits 12 on the wafer 10 is completed.

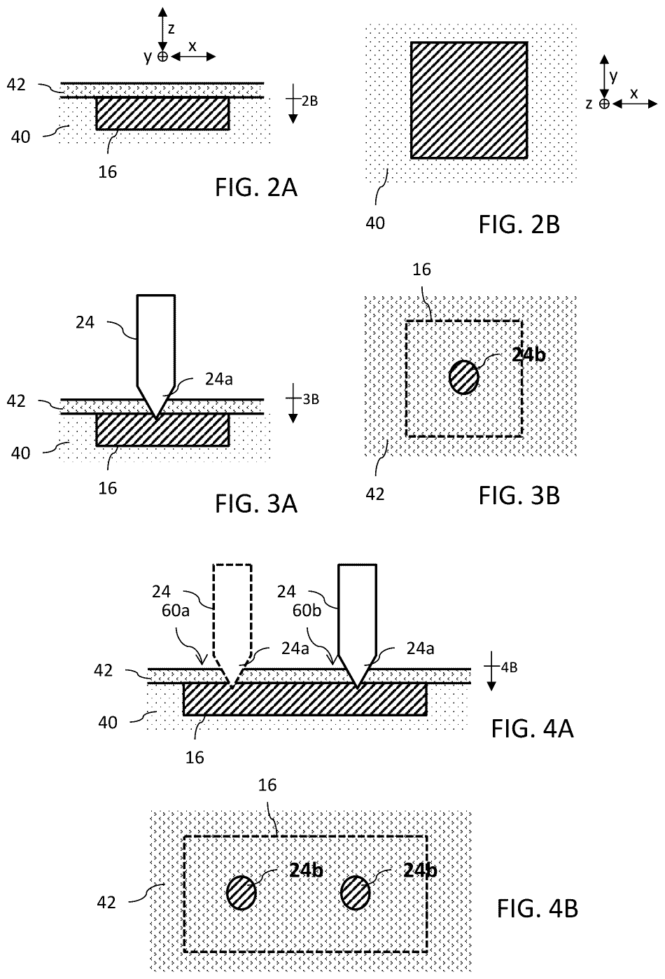

Reference is now made to FIGS. 2A and 2B which show a vertical cross-section view and a horizontal cross-section view, respectively, of a die pad 16 configured to be probed by a needle 24 during wafer level testing. The die pad 16 may be made, for example, of a copper or copper alloy material. The die pad 16 may be provided within an insulating layer 40 made, for example, of an oxide layer, and is covered by a protection layer 42 (not shown in FIG. 2B) made, for example, of silicon dioxide, aluminum oxide, magnesium oxide, or the like. This protection layer 42 may comprise a passivation layer as known in the art. It will be noted that an integrated circuit may include many die pads 16, and not all included die pads will necessarily participate in the wafer level testing operation. Indeed, some die pads may be wafer test die pads only, while other die pads may be used to create electrical interconnections such as wire bonding or bumps or vias.

When performing wafer level testing, the distal end 24a of the needle 24 punctures through the protection layer 42 and partially into the upper surface of the die pad 16 as shown in FIG. 3A. After the needle 24 is withdrawn, a probe mark 24b is left on the die at the location of the puncture as shown in FIG. 3B. Following the withdrawal of the needle 24, the upper surface of the die pad 16 is scarred and exposed to air. The exposed surface of the die pad 16 will subsequently oxidize and corrode within the wafer testing environment.

Some aspects of wafer level testing require the probing of a given die pad 16 more than one time. In order to ensure good mechanical and electrical contact with the die pad 16 during each probing action, the horizontal and vertical translation of the wafer 10 relative to the probe card 22 is controlled to ensure that the distal end 24a of the needle 24 punctures through the protection layer 42 and partially into the upper surface of the die pad 16 at two distinct locations. The reason for this is that the oxidization and corrosion at the surface of the die pad 16 resulting from the first probe contact may preclude the making of a clean and effective electrical connection between the distal end 24a of the needle 24 and the die pad 16 if the second probe contact is made at or about the first probe contact location.

To account for the need to probe a given die pad 16 more than one time during wafer level testing, the size, shape and orientation of the die pad are designed to permit multiple probe contacts at horizontally (x-y plane) offset locations. This is shown in FIG. 4A where a first probe contact (dashed lines) is made at a first location 60a on the die pad 16 and a second probe contact (solid lines) is made at a second location 60b on the same die pad 16.

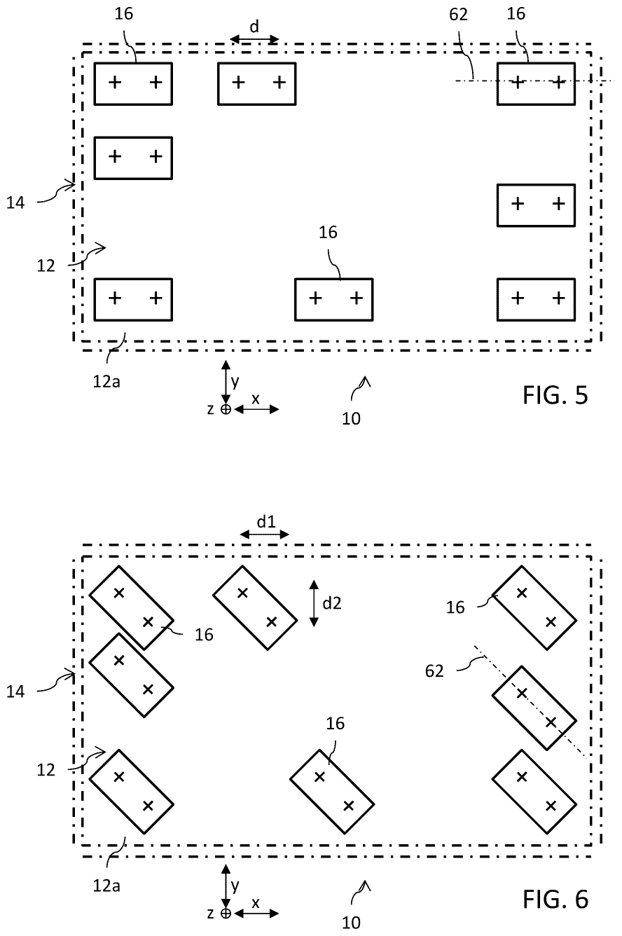

Reference is now made to FIG. 5 which shows a top plan view of an area 12a where an integrated circuit 12 is located on a wafer 10. The integrated circuit 12 includes a plurality of die pads 16 each having an identical size, geometric shape and orientation that is configured to permit multiple probe contacts at horizontally offset (in the x-y plane) locations. In the example shown in FIG. 5, the geometric shape of each die pad is a rectangle, the orientation of each die pad has a longitudinal bisector 62 (i.e., the major axis or line of reflectional symmetry) of the rectangle extending in the x direction, and the size of each die pad provides an area large enough to accommodate two probe contacts (at locations marked “+”) that are horizontally offset from each other in the x direction. To accomplish the probing operation, the wafer 10 is horizontally translated in the x-y plane to a position where the needles 24 are aligned with the die pads 16 of the integrated circuit 12 at the first “+” location and then the wafer 10 is vertically translated in the z direction so that the probe needles 24 puncture through the protective layer and make physical and electrical contact with the die pads 16 at the first location. A testing equipment 30 applies power and signals to the die through the needles 24 of the probe card 22 and read signals output from the die (the power/signals generally indicated by double headed arrow 32) in connection with performing a first electrical testing of the die. The wafer 10 is then retracted in the z direction and horizontally translated in the x direction (parallel to the scribe area 14 and the peripheral edge of the die) by a distance “d” to a position where the needles 24 are aligned with the die pads 16 of the integrated circuit 12 at the second “+” location and then the wafer 10 is vertically translated in the z direction so that the probe needles 24 puncture through the protective layer and make physical and electrical contact with the die pads 16 at the second location. The testing equipment 30 applies power and signals to the die through the needles 24 of the probe card 22 and read signals output from the die (the power/signals generally indicated by double headed arrow 32) in connection with performing a second electrical testing of the die. From the read signals output from the die from one or more of the first and second electrical testing, the testing equipment 30 may determine whether the die is defective.

Reference is now made to FIG. 6 which shows a top plan view of an area 12a where an integrated circuit 12 is located on a wafer 10. The integrated circuit 12 includes a plurality of die pads 16 each having an identical size, geometric shape and orientation that is configured to permit multiple probe contacts at horizontally offset (in the x-y plane) locations. In the example shown in FIG. 6, the geometric shape of each die pad is a rectangle, the orientation of each die pad has a longitudinal bisector 62 (i.e., the major axis or line of reflectional symmetry) of the rectangle extending in a generally diagonal direction (more specifically here at 45°, and only by example, without limitation) with reference to the geometric shape of the area 12a, and the size of each die pad provides an area large enough to accommodate two probe contacts (at locations marked “+”) that are horizontally (x-y plane) offset from each other in that diagonal direction. To accomplish the probing operation, the wafer 10 is horizontally translated in the x-y plane to a position where the needles 24 are aligned with the die pads 16 of the integrated circuit 12 at the first “+” location and then the wafer 10 is vertically translated in the z direction so that the probe needles 24 puncture through the protective layer and make physical and electrical contact with the die pads 16 at the first location. A testing equipment 30 applies power and signals to the die through the needles 24 of the probe card 22 and read signals output from the die (the power/signals generally indicated by double headed arrow 32) in connection with performing a first electrical testing of the die. The wafer 10 is then retracted in z-direction and horizontally translated in the x-y plane with an x direction distance “d1”—parallel to the scribe area 14 and one edge of the die—and a y direction distance “d2”—parallel to the scribe area 14 and a perpendicular edge of the die—to a position where the needles 24 are aligned with the die pads 16 of the integrated circuit 12 at the second “+” location and then the wafer 10 is vertically translated in the z direction so that the probe needles 24 puncture through the protective layer and make physical and electrical contact with the die pads 16 at the second location. The testing equipment 30 applies power and signals to the die through the needles 24 of the probe card 22 and read signals output from the die (the power/signals generally indicated by double headed arrow 32) in connection with performing a second electrical testing of the die. From the read signals output from the die from one or more of the first and second electrical testing, the testing equipment 30 may determine whether the die is defective.

The reference to a rectangle for the geometrical shape of each die pad 16 is by example only. Other geometrical shapes may be used including, for example, square, circular, ovular, triangular, etc.

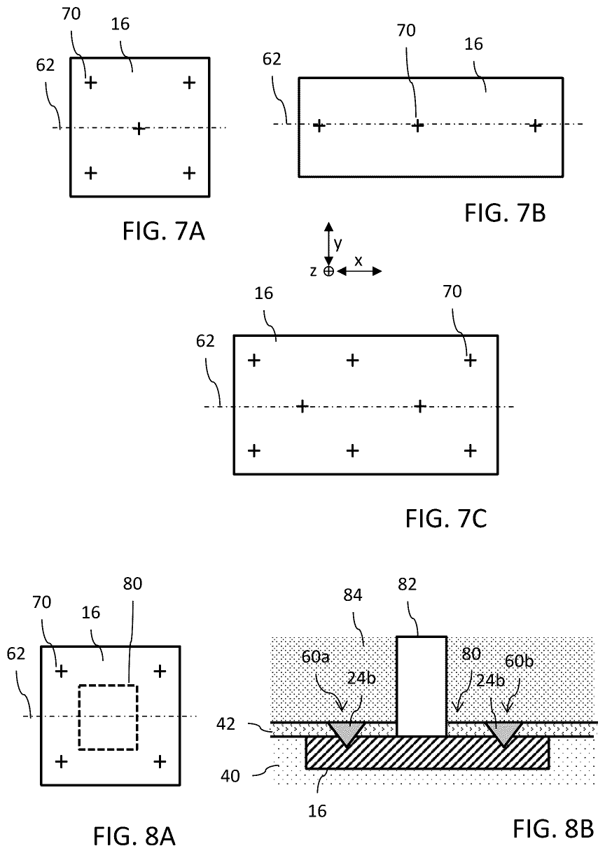

The reference to two probe contact locations within the area of each die pad 16 is by example only. It will be understood that three or more probe contact locations may be defined with respect to each die pad. See, for example: FIG. 7A showing a square geometric shape supporting five horizontally offset probe contact locations 70 (marked with a “+”); FIG. 7B showing a rectangle geometric shape supporting three horizontally offset probe contact locations 70; and FIG. 7C showing a rectangle geometric shape supporting eight horizontally offset probe contact locations 70.

With reference to FIG. 8A, the plural probe contact locations may be arranged within the area of each pad 16 so as to reserve a sub-area 80 (indicated by dashed line) where the wafer level testing will not make a probe contact. This reserved sub-area 80 is left undamaged by probing and is thus available for use in connection with creating an electrical connection (such as with a wire bond or ball bond or pillar bond (not explicitly shown) or a bump or a via when packaging the integrated circuit die. This is illustrated, by example, in FIG. 8B, where probing has been made at the locations 60a and 60b, leaving probe marks 24b, and the protection layer 42 has been selectively removed at the location of the reserved sub-area 80 to permit attachment of the electrical connection 82. The shading of the probe marks 24b in FIG. 8B is meant to illustrate the presence of oxidation or corrosion which can occur after the probe tip has been withdrawn. The electrical connection 82 with the die pad 16 may be created using, for example, a laser assisted process such as a Laser Induced Strip Interconnect (LISI) process to create a via or line directly inside a molding layer 84 of the package that contains the integrated circuit 12.

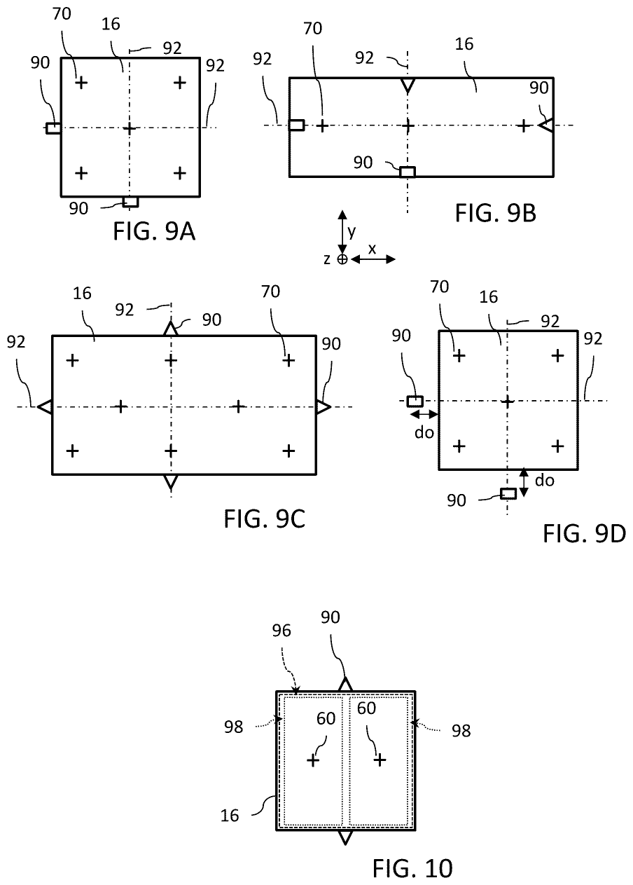

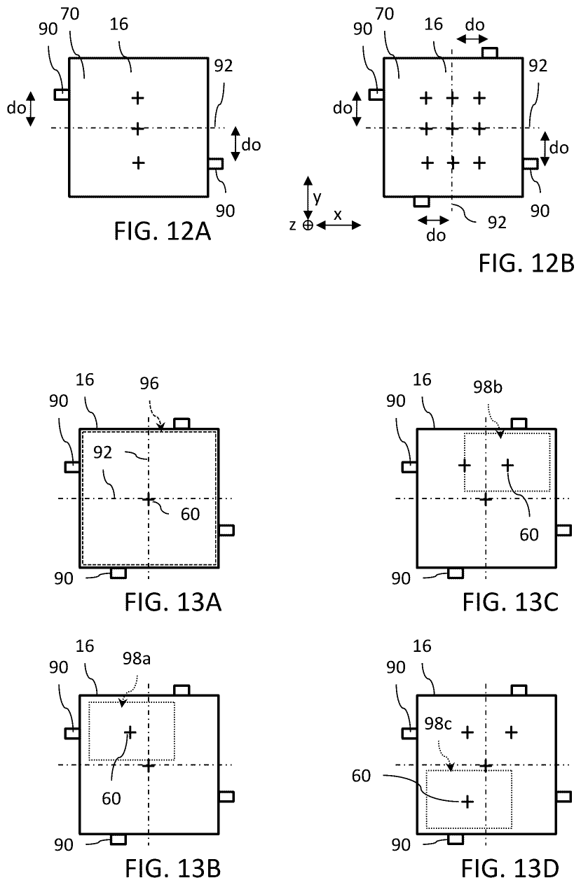

To assist the wafer level test equipment 20 in the horizontal (x direction and y direction) translation of the wafer 10 relative to the probe card 22 to align the needles 24 with the probe locations 60 on the die pad 16, one or more die pads of the integrated circuit, and perhaps many or all of the die pads, can include fiducial (or alignment) marks 90 as shown in FIGS. 9A to 9D. The marks 90 can be of any selected geometric shape (examples are shown for rectangular and triangular shapes). The marks 90 can be located either inside the outer perimeter of the die pad or outside the outer perimeter of the die pad. For marks located inside the outer perimeter of the die pad, the marks may be placed immediately adjacent to a side edge of the die pad or offset inside from the side edge of the die pad. For marks located outside the outer perimeter of the die pad, the marks may be placed immediately adjacent to a side edge of the die pad or offset outside by a distance “do” from the side edge of the die pad. In one embodiment, the marks 90 are generally positioned coincident with a line of reflectional symmetry 92 of the geometric shape of the die pad 16 (see, FIGS. 9A-9C). In another embodiment, the marks 90 may be positioned symmetrically offset, for example, by a distance “do” from a line of reflectional symmetry 92 of the geometric shape of the die pad 16 (see, FIGS. 12A-12B).

The fiducial (or alignment) marks 90 are detected by optical sensor devices 21 (for example, a camera with an image processing system as shown in FIG. 1A) of the wafer level test equipment 20 and used to detect the location, size and shape of the die pads and control the horizontal (x-y plane) translation of the wafer 10 relative to the probe card 22. For example, there is a physical pad provided by the die pad 16 itself (indicated by the dashed box outline 96) and the optically detected fiducial (or alignment) marks 90 can be used by the wafer level test equipment 20 to define two or more logical pads (indicated by the dotted box outline 98) within each physical pad. For example, the located edge(s) of the physical pad 96 and the located position(s) of the fiducial (or alignment) marks 90 are used by an image processing algorithm to define the side edges of the two or more logical pads 98. Having defined the location of the logical pads, the wafer level test equipment 20 can then control the horizontal (x-y plane) translation of the wafer 10 to place the needles 24 of the probe card 22 at probe locations 60 located inside the area of the logical pads 98 at or substantially coincident with the geometric center of each logical pad (or with an offset with respect to the geometric center of each logical pad).

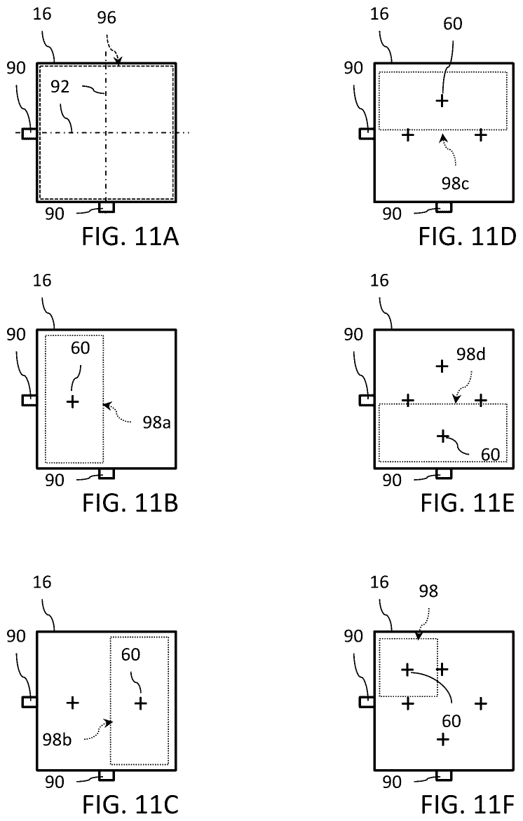

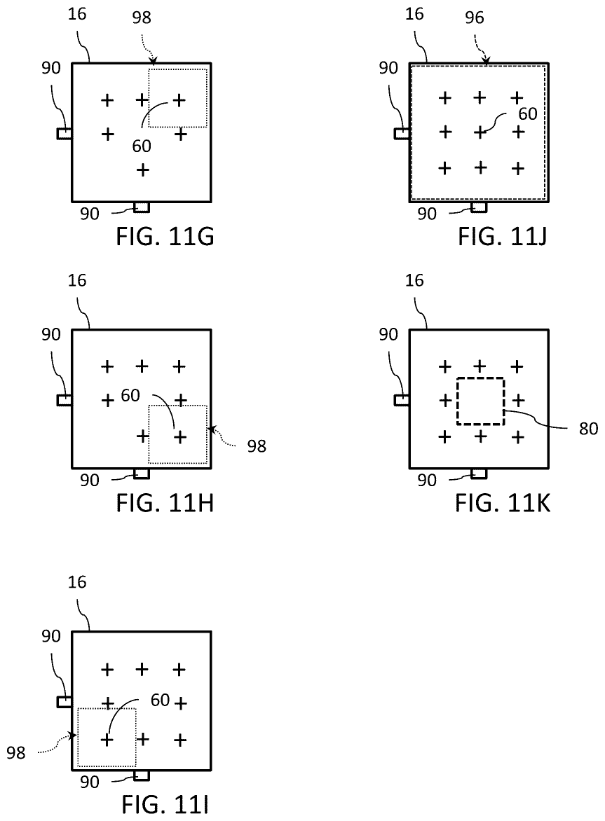

Reference is now made to FIGS. 11A-11K showing execution of a series of processing steps by the wafer level test equipment 20 in performing multiple probe operations on a die pad 16 using fiducial (or alignment) marks 90 positioned coincident with a line of reflectional symmetry 92 of the geometric shape of the die pad 16. In FIG. 11A, the optical sensor devices 21 of the wafer level test equipment 20 detect the fiducial (or alignment) marks 90 and the wafer level test equipment 20 determines the location of the physical pad indicated by the dashed box outline 96. In FIG. 11B, the wafer level test equipment 20 determines, from the detected fiducial (or alignment) marks 90, the location of a first logical pad area indicated by the dotted box outline 98a, and the horizontal (x-y plane) translation of the wafer 10 is controlled to place the needle 24 of the probe card 22 at the probe location 60 located inside (for example, at the geometric center of) the first logical pad area 98a. In FIG. 11C, the wafer level test equipment 20 determines, from the detected fiducial (or alignment) marks 90, the location of a second logical pad area indicated by the dotted box outline 98b, and the horizontal (x-y plane) translation of the wafer 10 is controlled to place the needle 24 of the probe card 22 at the probe location 60 located inside (for example at the geometric center of) the second logical pad area 98b. In FIG. 11D, the wafer level test equipment 20 determines, from the detected fiducial (or alignment) marks 90, the location of a third logical pad area indicated by the dotted box outline 98c, and the horizontal (x-y plane) translation of the wafer 10 is controlled to place the needle 24 of the probe card 22 at the probe location 60 located inside (for example, at the geometric center of) the third logical pad area 98c. In FIG. 11D, the wafer level test equipment 20 determines, from the detected fiducial (or alignment) marks 90, the location of a fourth logical pad area indicated by the dotted box outline 98d, and the horizontal (x-y plane) translation of the wafer 10 is controlled to place the needle 24 of the probe card 22 at the probe location 60 located inside (for example, at the geometric center of) the second logical pad area 98d. This process can be repeated as shown in FIGS. 11F-11I to define further logical pad areas 98 and control placement of the needle 24 at probe locations 60 inside those areas. In FIG. 11J, the location of the physical pad indicated by the dashed box outline 96 (FIG. 11A) can be used to control the horizontal (x-y plane) translation of the wafer 10 to place the needle 24 of the probe card 22 at the probe location 60 located inside (for example, at the geometric center of) the pad. Alternatively, as shown in FIG. 11K, the sub-area 80 (indicated by dashed line) where the wafer level testing will not make a probe contact is reserved for the creation of an electrical connection (such as a wire bond, bump, pillar, via, etc.).

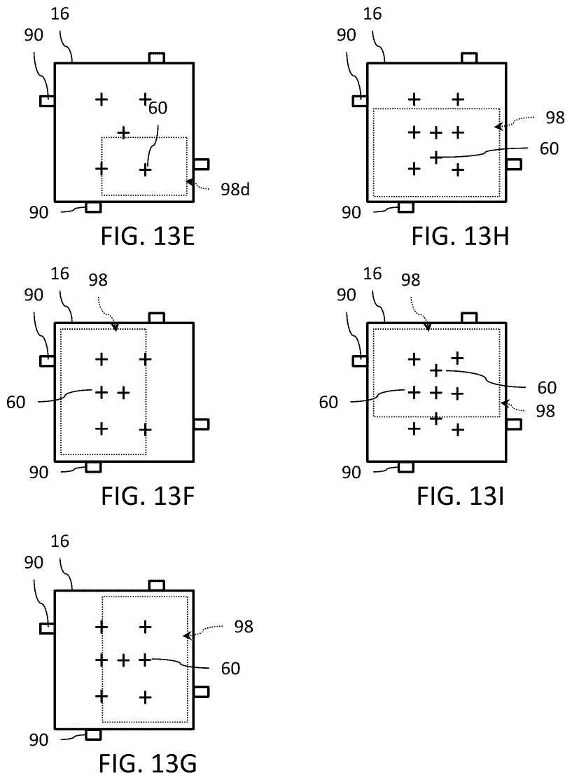

Reference is now made to FIGS. 13A-13I showing execution of a series of processing steps by the wafer level test equipment 20 in performing multiple probe operations on a die pad 16 using fiducial (or alignment) marks 90 positioned symmetrically offset from lines of reflectional symmetry 92 of the geometric shape of the die pad 16. In FIG. 13A, the optical sensor devices 21 of the wafer level test equipment 20 detect the fiducial (or alignment) marks 90 and the wafer level test equipment 20 determines the location of the physical pad indicated by the dashed box outline 96. At this point, the horizontal (x-y plane) translation of the wafer 10 may be controlled to place the needle 24 of the probe card 22 at the probe location 60 located inside (for example, at the geometric center of) the physical pad 96. In FIG. 13B, the wafer level test equipment 20 determines, from the detected fiducial (or alignment) marks 90, the location of a first logical pad area indicated by the dotted box outline 98a, and the horizontal (x-y plane) translation of the wafer 10 is controlled to place the needle 24 of the probe card 22 at the probe location 60 located inside (for example, at the geometric center of) the first logical pad area 98a. In FIG. 13C, the wafer level test equipment 20 determines, from the detected fiducial (or alignment) marks 90, the location of a second logical pad area indicated by the dotted box outline 98b, and the horizontal (x-y plane) translation of the wafer 10 is controlled to place the needle 24 of the probe card 22 at the probe location 60 located inside (for example, at the geometric center of) the second logical pad area 98b. In FIG. 13D, the wafer level test equipment 20 determines, from the detected fiducial (or alignment) marks 90, the location of a third logical pad area indicated by the dotted box outline 98c, and the horizontal (x-y plane) translation of the wafer 10 is controlled to place the needle 24 of the probe card 22 at the probe location 60 located inside (for example, at the geometric center of) the third logical pad area 98c. In FIG. 13E, the wafer level test equipment 20 determines, from the detected fiducial (or alignment) marks 90, the location of a fourth logical pad area indicated by the dotted box outline 98d and the horizontal (x-y plane) translation of the wafer 10 is controlled to place the needle 24 of the probe card 22 at the probe location 60 located inside (for example, at the geometric center of) the fourth logical pad area 98d. This process can be repeated as shown in FIGS. 13F-13I to define further logical pad areas 98 and control placement of the needle 24 at probe locations 60 inside those areas.

The markers 90 may be created in many ways. For example, a marker 90 may comprise an additional portion of the die pad 16 (such as a patterned extension), or the absence of a portion of the die pad 16 (such as a patterned notch). In another way, an additional layer (not explicitly shown in the cross-sectional views) of dielectric material may be placed between the protection layer 42 and the die pad 16 (and insulating layer 40), with this additional layer being patterned to provide the markers 90. This additional layer may, for example, comprise a passivation layer.

Moreover, in the state of the art, the wafer 10 is translated with respect to the probe card 22 under the control of the wafer level test equipment 20 as discussed above. However, this is not a limitation as in an alternative configuration the probe card 22 could instead be translated under the control of the wafer level test equipment 20 relative to the wafer 10.

Still further, in an embodiment the wafer level test equipment 20 may control translations of both the wafer 10 and the probe card 22.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

1. A method, comprising:
performing wafer level testing of a wafer including integrated circuit dies, each integrated circuit die including a plurality of die pads, each die pad covered by a protection layer;
wherein performing comprises, at a given die pad of said plurality of die pads:
puncturing through the protection layer with a distal end of a probe to make physical and electrical contact with the given die pad at a first location at the given die pad;
performing a first electrical test of the integrated circuit die through the probe;
horizontally translating after completion of the first electrical test;
puncturing through the protection layer with the distal end of the probe to make physical and electrical contact with the given die pad at a second location, different from the first location, at the given die pad; and
performing a second first electrical test of the integrated circuit die through the probe.

2. The method of claim 1, wherein performing comprises:
identifying a physical pad of the given die pad;
identifying a first logical pad area within the physical pad;
positioning the probe at the first location which is inside the first logical pad area;
identifying a second logical pad area within the physical pad;
positioning the probe at the second location which is inside the second logical pad.

3. The method of claim 2, wherein the given die pad includes one or more fiducial markers, and further comprising:
optically detecting the one or more fiducial markers; and
processing a location of the detected one or more fiducial markers to identify the first logical pad area and identify the second logical pad area.

4. The method of claim 3, wherein said one or more fiducial markers are located inside an outer perimeter of the given die pad.

5. The method of claim 3, wherein said one or more fiducial markers are located offset by a distance from an outer perimeter of the given die pad.

6. The method of claim 3, wherein said one or more fiducial markers are located outside an outer perimeter of the given die pad.

7. The method of claim 3, wherein the given die pad has a geometric shape characterized by one or more lines of reflectional symmetry, and wherein said one or more fiducial markers are aligned with said one or more lines of reflectional symmetry.

8. The method of claim 3, wherein the given die pad has a geometric shape characterized by one or more lines of reflectional symmetry, and wherein said one or more fiducial markers are symmetrically offset from said one or more lines of reflectional symmetry.

9. The method of claim 1, wherein the given die pad has a geometric shape characterized by a line of reflectional symmetry, and wherein horizontally translating comprises moving either the wafer or the probe in a direction parallel to that line of reflectional symmetry.

10. The method of claim 9, wherein the geometric shape is selected from the group consisting of square and rectangular.

11. The method of claim 9, wherein each of the first and second locations is located on said line of reflectional symmetry.

12. The method of claim 1, wherein the given die pad includes a reserved area where neither the first location nor the second location are permitted, and further comprising performing an electrical connection to the die pad at a location within the reserved area.

13. The method of claim 1, further comprising determining whether the integrated circuit die is defective based on results of the first and second first electrical tests.

14. An integrated circuit die, comprising:
a plurality of wafer test die pads;
wherein each wafer test die pad is covered by a protection layer;
wherein each wafer test die pad has a geometric shape characterized by a major axis of reflectional symmetry;
wherein the major axes of reflectional symmetry for all of the plurality of wafer test die pads extend substantially parallel to each other; and
wherein a physical pad of each wafer test die pad in said plurality of wafer test die pads includes a first logical pad area within the physical pad with a first test probe mark through the protection layer located within the first logical pad area, and a second logical pad area within the physical pad with a second test probe mark through the protection layer located within the second logical pad area.

15. The integrated circuit die of claim 14, wherein the geometric shape is rectangular.

16. The integrated circuit die of claim 14, wherein the first test probe mark is located at or substantially coincident with a geometric center of the first logical pad and wherein the second test probe mark is located at or substantially coincident with a geometric center of the second logical pad.

17. The integrated circuit die of claim 14, wherein the first and second test probe marks are located on said major axis of reflectional symmetry.

18. The integrated circuit die of claim 14, wherein each wafer test die pad includes one or more fiducial markers located inside an outer perimeter of the wafer test die pad.

19. The integrated circuit die of claim 14, wherein each wafer test die pad includes one or more fiducial markers located offset by a distance from an outer perimeter of the wafer test die pad.

20. The integrated circuit die of claim 14, wherein each wafer test die pad includes one or more fiducial markers are located outside an outer perimeter of the wafer test die pad.

21. The integrated circuit die of claim 14, wherein each wafer test die pad includes one or more fiducial markers are aligned with said major axis of reflectional symmetry.

22. The integrated circuit die of claim 14, wherein each wafer test die pad includes one or more fiducial markers symmetrically offset from said major axis of reflectional symmetry.

23. The integrated circuit die of claim 14, wherein the wafer test die pad includes a reserved area where neither the first location nor the second location are permitted, and further comprising an electrical connection to the wafer test die pad at a location within the reserved area.
